(19) United States
(12) Patent Application Publication
(10) Pub. No.: US 2024/0095422 A1
(43) Pub. Date: Mar. 21, 2024

(54) A METHOD FOR VIRTUAL TESTING OF A HEAD UNIT OF A MOTOR VEHICLE BY A VIRTUAL TEST BENCH AS WELL AS A CORRESPONDING VIRTUAL TEST BENCH

(71) Applicant: MERCEDES-BENZ GROUP AG, Stuttgart (DE)

(72) Inventor: Rodrigo NUNES, Edmonds, WA (US)

(21) Appl. No.: 18/275,040

(22) PCT Filed: Jan. 17, 2022
(86) PCT No.: PCT/EP2022/050826

§ 371 Date: Jul. 31, 2023

(30) Foreign Application Priority Data
Feb. 1, 2021 (GB) GB2101341.2

(51) Int. Cl. G06F 30/20

(52) U.S. Cl. CPC G06F 30/20

(57) ABSTRACT

A method for virtual testing of a head unit of a motor vehicle by a virtual test bench involves a data communication between a decentral electronic computing device and a central electronic computing device. An input of a user of the decentral electronic computing device is transmitted to the central electronic computing device via the data communication. The input of the user is virtually tested depending on the provided characterizing software. A result of the virtual test is transmitted to the decentral electronic computing device via the data communication and the result is displayed on a display device of the decentral electronic computing device for the user.

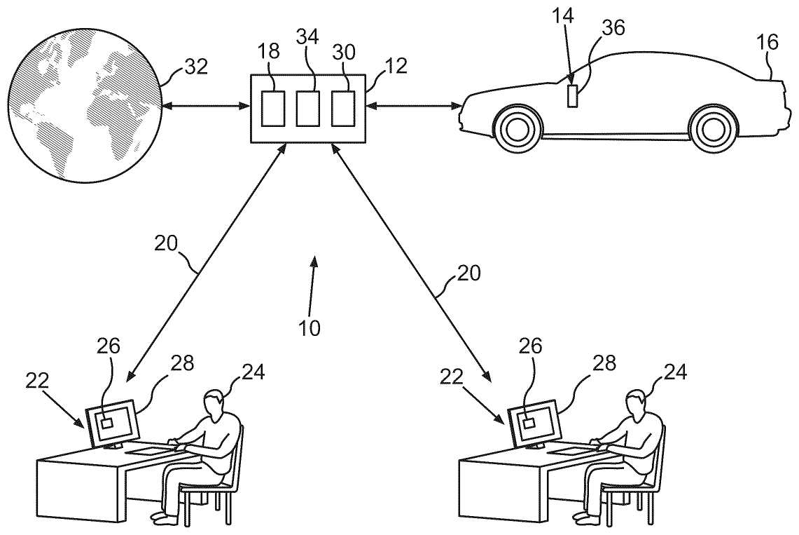

### FIELD OF THE INVENTION

Exemplary embodiments of the invention relate to the field of automobiles, and more specifically to a method for virtual testing of at least one head unit of at least one motor vehicle by a virtual test bench, a corresponding computer program product as well as a corresponding virtual test bench.

### BACKGROUND INFORMATION

Currently, one of the major roadblocks of testing vehicle head unit applications is that they need to be deployed to a physical test vehicle or a hardware test bench. The test bench is a simulation device that has parts of the main entertainment components of a motor vehicle, for example a dashboard screen, the telematic control unit that performs communication with, for example, a backend system and a CAN bus and other vehicle emulation devices that are usually bulky and stored in test rooms across a company. Furthermore, these test benches are expensive and scarce. If developers want to test their head unit applications, they need to physically reserve one of these devices, are sometimes required to commute to a different building on the campus or have to travel to a location that is equipped with one of these units with their specification. This means considerable effort is required just to perform tests of the team's software and validate corresponding behavior.

EP 2 895 347 A2 discloses a system and method for monitoring apps in a vehicle to reduce driver distraction. A controller operating inside or in combination with the head unit of the vehicle may monitor operation of the vehicle and generate alerts indicative of operation of the vehicle. In response to the alert, the operation of the app in the vehicle may be modified.

DE 10 2017 109 132 A1 relates to a method for model-based testing of software for a vehicle application system, in particular for a driver assistance system, and for providing corresponding test results. It is envisaged that the software is tested by an information and data processing infrastructure provided in a computer cloud for model-based testing of the software, incorporating parameters of the vehicle application system set during ongoing operation of at least one corresponding vehicle.

### SUMMARY OF THE INVENTION

Exemplary embodiment of the invention are directed to a method, a computer program product, as well as a virtual test bench, by which a user of the virtual test bench may efficiently test a head unit of a motor vehicle.

One aspect of the invention relates to a method for virtual testing of at least one head unit of at least one motor vehicle by a virtual test bench. A central electronic computing device of the virtual test bench is provided and at least one characterizing software of the at least one head unit on the central electronic computing device is provided. A data communication is enabled between a decentral electronic computing device and the central electronic computing device. An input of a user of the decentral electronic computing device is transmitted to the central electronic computing device. The input of the user is virtually tested depending on the provided characterizing software by the central electronic computing device. The result of the virtual test is transmitted to the decentral electronic computing device by the central electronic computing device and the result is displayed on a display device of the decentral electronic computing device for the user.

The virtual test bench introduces a modernized concept to provision different combinations of emulated components on the central electronic computing device, allowing teams to journey through the project of new motor vehicle lines with full focus on their individual domains while constantly integrating with all other internally and externally maintained components at any given moment. It also allows teams to decouple their processes and working velocity from others, by maintaining a centralized repository of versions that may be validated as a whole and integrated as a super set of components that emulate a motor vehicle. The platform facilitates the creation of “mocks”, with the intent of emulating the behavior of individual components and creating infinite amounts of conditions, inputs and outputs to be evaluated as a unit and simulating real-world internal and external conditions. The virtual test bench platform introduces software tools for easy simulation of conceptual components before they are fabricated, potentially saving the company money, while testing them in the context of an ongoing project.

Another benefit of this embodiment is the capability of automatic end-to-end testing at very early stages of development, by provisioning ephemeral test benches on demand in a decentralized electronic computing device platform in order to validate individual siloed software builds.

According to the presented embodiment, the quality assurance life cycle is pushed to an earlier stage, allowing individual development teams to measure the impact of their individual domain components by constantly verifying their changes against all the latest software out of their control, for multiple motor vehicle lines and variances inside them. An end-to-end software pipeline testing is allowed and a validation in an automatic way, removing the need to obtain the necessary software for other vehicle components, allowing each team to move at their own speed while maintaining the state of quality of the whole motor vehicle project at a stable and verifiable state is realized. A platform is created to prototype and test new and existing applications in future motor vehicle lines before other hardware and software components are available, allowing software applications and vehicle functionality to be emulated via conceptual interfaces, and input and output combinations of values to be synthetically injected in the platform in high volumes and with low entry barriers.

Teams may share concepts, features and applications easily across regions and geographies internally and externally, via the central electronic computing device that allows remote collaboration, access and locally emulated screens and components for demonstrations, developments and testing.

The characterizing software may characterize, for example, an application on the head unit or a software on the head unit or a hardware on the head unit. In particular, the characterizing software describes the at least one head unit as a whole. In other words, with the characterizing software the head unit may be simulated.

In an embodiment, at least two different versions of the characterizing software are provided on the central electronic computing device and the input is virtually tested by the at least two versions simultaneously. For example, an older version of the characterizing software and a new version of the characterizing software may be provided on the central electronic computing device and the input is virtually tested on both versions of the characterizing software. Therefore, the input may be tested on the different versions and the user of the decentral electronic computing device may obtain the results for both versions. Therefore, a complete virtual simulation of the head unit is realized.

In another embodiment, the at least two different versions are provided for at least two different regions. In particular, very specific versions of the software are provided in any of the geographic regions, for example, China, America and Europe. Therefore, the input is simulated for every region, wherein a complete virtual simulation of the head unit is realized by the virtual test bench.

In another embodiment, the central electronic computing device is provided as a cloud server. Alternatively, the central electronic computing device may be a local central electronic computing device. According to the embodiment as a cloud server, the virtual test bench abstracts most of the functionality in the cloud, which allows mocking of expensive components with very cheap software, and avoiding the need of acquiring and maintaining hardware and base software, which can be rented on demand in cloud providers, in pay-per-use modes.

In a further embodiment, a plurality of different characterizing software are provided by the central electronic computing device and the input is virtually tested by the plurality of different characterizing software. In particular, the at least one head unit may be simulated by using a plurality of different characterizing software, for example, different applications on the head unit. In particular, the different characterizing software are tested simultaneously. Therefore, a complete simulation of the head unit is realized by using the virtual test bench.

In another embodiment, the provided characterizing software is editable by an operator of the central electronic computing device. In particular, the maintenance of the head unit software versions, configurations, cable connections, and hardware settings are replaced by configuration files centrally deployed by a single operator, who may complete the operation from anywhere in the world in a fraction of the time, in a reducible process that may be executed in bulk, for example, updated software versions of all test benches, patch the latest versions, fix a bug and restart. The dynamic configuration makes the virtual test bench not only reusable, but instantly reconfigurable. Current physical virtual test benches have, for example, a vehicle identification number, that is associated with it and hard to reconfigure. The user needs to associate their test applications to that vehicle identification number to use it, when they book a time slot for their testing. The virtual test bench allows anybody to use a virtual motor vehicle and start the virtual test bench directly with their own configurations, applications and environment and that virtual testbenches may be created on demand for cases when teams needed long test periods or multiple hours reserved, in a “dedicated” model.

According to another embodiment, a plurality of different head units of a plurality of different motor vehicles is virtually tested by the virtual test bench. For example, testing an application in multiple versions of the head unit software, is cumbersome. This may take days until developers find a place where they may go for testing their applications in the specific versions of the different head units. The virtual test bench may all be put together in virtual groups where the user can simultaneously test the application in many different versions and the many different versions of the head units of different motor vehicles. Furthermore, the virtual test bench allows instant flashing and a total return to a “clean state” after each individual use. Therefore, a complete testing of the different head units is realized by the virtual test bench.

In a further embodiment, the central electronic computing device comprises a display emulator for virtual testing of a virtual display of the at least one head unit, and the virtual display is transmitted and displayed on the display device. For example, installing and configuring a display in a test bench is almost always a one-time process, since it is currently very complicated. The virtual test bench may have the virtual display emulators deployed and updated in the cloud server by specialized teams that are not always available to go on-site and help local teams. The virtual display is forwarded over the network communication to the decentral electronic computing device, which may be configured as a laptop, and all controls, which are available in the real motor vehicle, allow the user to control its function, interact with the virtual touch screen and see the exact reactions and “look and feel” of the real display. This is a very valuable feature for a developer, product owner or anybody who wants to share design/functionality in a realistic setting with the other stakeholders or during the development phase. It also allows the decentralized testing of multiple types of display devices from different car lines, with different form factors and capabilities. This allows developers to evaluate the behavior of their display applications in different, “mock” conditions that mirror the screen model on the vahicle dashboard.

The shown method is, in particular, a computer-implemented method. Therefore, another aspect of the invention relates to a computer program product comprising computer instructions for performing the method according to the preceding aspect, when the computer instructions are computed by an electronic computing device. Furthermore, the invention relates to a computer-readable storage medium, comprising the computer program product. The computer-readable storage medium may be stored in the electronic computing device.

A still further aspect of the invention relates to a virtual test bench for a virtual testing of at least one head unit of at least one motor vehicle, comprising at least one central electronic computing device, wherein the virtual test bench is configured to perform a method according to the preceding aspect. In particular, the method is performed by the virtual test bench.

Advantageous forms of configuration of the method are to be regarded as advantageous forms of the computer program product, the computer-readable storage medium as well as the virtual test bench. Therefore, the virtual test bench comprises means for performing the method.

Further advantages, features, and details of the invention derive from the following description of preferred embodiment as well as from the drawing. The features and feature combinations previously mentioned in the description as well as the features and feature combinations mentioned in the following description of the FIGURE and/or shown in the FIGURE alone can be employed not only in the respectively indicated combination but also in any other combination or taken alone without leaving the scope of the invention.

### BRIEF DESCRIPTION OF THE SOLE DRAWING

The novel features and characteristic of the disclosure are set forth in the appended claims. The accompanying drawing, which is incorporated in and constitutes a part of this disclosure, illustrates an exemplary embodiment and together with the description, serves to explain the disclosed principles. The same numbers are used throughout the FIGURE to reference like features and components. Some embodiments of system and/or methods in accordance with embodiments of the present subject matter are now described below, by way of example only, and with reference to the accompanying FIGURE.

The sole FIGURE shows in a schematic side view an embodiment of a virtual test bench.

In the FIGURE same elements or elements having the same function are indicated by the same reference signs.

### DETAILED DESCRIPTION

In the present document, the word “exemplary” is used herein to mean “serving as an example, instance, or illustration”. Any embodiment or implementation of the present subject matter described herein as “exemplary” is not necessarily to be construed as preferred or advantageous over other embodiments.

While the disclosure is susceptible to various modifications and alternative forms, specific embodiments thereof have been shown by way of example in the drawing and will be described in detail below. It should be understood, however, that it is not intended to limit the disclosure to the particular forms disclosed, but on the contrary, the disclosure is to cover all modifications, equivalents, and alternatives falling within the scope of the disclosure.

The terms “comprises”, “comprising”, or any other variations thereof, are intended to cover a non-exclusive inclusion so that a setup, device or method that comprises a list of components or steps does not include only those components or steps but may include other components or steps not expressly listed or inherent to such setup or device or method. In other words, one or more elements in a system or apparatus preceded by “comprises” or “comprise” does not or do not, without more constraints, preclude the existence of other elements or additional elements in the system or method.

In the following detailed description of the embodiment of the disclosure, reference is made to the accompanying drawing that forms part hereof, and in which is shown by way of illustration a specific embodiment in which the disclosure may be practiced. This embodiment is described in sufficient detail to enable those skilled in the art to practice the disclosure, and it is to be understood that other embodiments may be utilized and that changes may be made without departing from the scope of the present disclosure. The following description is, therefore, not to be taken in a limiting sense.

The sole FIGURE shows a schematic side view according to an embodiment of a virtual test bench 10. The virtual test bench 10 comprises at least one central electronic computing device 12. The virtual test bench is configured to perform a virtual testing of at least one head unit 14 of at least one motor vehicle 16.

According to an embodiment of the invention, a method for virtual testing of the at least one head unit 14 of the at least one motor vehicle 16 by the virtual test bench 10 is presented. The central electronic computing device 12 is provided and at least one characterizing software 18, 30 of the at least one head unit 14 is provided on the central electronic computing device 12. A data communication 20 is enabled between a decentral electronic computing device 22 and the central electronic computing device 12. An input of a user 24 of the decentral electronic computing device 22 is transmitted to the central electronic computing device 12. The input of the user 24 is virtually tested depending on the provided characterizing software 18, 30 by the central electronic computing device 12. A result 26 of the virtual test is transmitted to the decentral electronic computing device 22 and the result 26 is displayed on a display device 28 of the central electronic computing device 12 for the user 24.

According to an embodiment, at least two different versions of the characterizing software 18, 30 are provided on the central electronic computing device 12 and the input is virtually tested with the at least two versions 18, 30 simultaneously. In particular, at least the two different versions 18, 30 are provided for at least two different regions 32.

In another embodiment, a plurality of different characterizing software 18, 30 are provided by the central electronic computing device 12, and the input is virtually tested by the plurality of different characterizing software 18, 30. The provided characterizing software 18, 30 is editable by an operator of the central electronic computing device 12. Furthermore, a plurality of different head units 14 of a plurality of different motor vehicles 16 may be virtually tested by the virtual test bench 10.

In this embodiment, the central electronic computing device 12 is provided as a cloud server. Alternatively, the central electronic computing device 12 may be provided as a local central electronic computing device.

Furthermore, the central electronic computing device 12 comprises a display emulator 34 for virtual testing of a virtual display 36 of the at least one head unit 40 and the virtual display 36 is transmitted and displayed on the display device 28. The central electronic computing device 12 may comprise more than one virtual displays 36.

According to the embodiment, the virtual test bench 10 deploys emulators of the head unit 14 to the central electronic computing device 12 and allows developers, which are presented with two users 24, product owners, managers, and executers to simply securely connect from any company laptop, for example, the decentral electronic computing device 22, to the central electronic computing device 12 running very specific versions of the head unit software 18, 30 in any of the geographic regions 32, for example, China, America or Europe, for which in car applications are provided. This improves many processes currently in place, saving money, time and allowing otherwise impossible or virtually impossible tasks to be accomplished.

The virtual test bench 10 requires little or no physical space. The virtual test bench 10 abstracts most of the functionality in the cloud, allowing mocking of expensive components with cheap or very cheap software. The maintenance of the software versions 18, 30, configuration, cable connections, and hardware settings are replaced by configuration files centrally deployed by a single operator, who may perform the operation from anywhere in the world in a fraction of the time, in a reproducible process that may be executed in bulk, for example by updating software versions of all test benches, patching the latest versions, fixing a bug, and restarting. The dynamic configuration makes the virtual test bench 10 not only reusable, but instantly reconfigurable. The virtual test bench 10 allows anybody to use a virtual motor vehicle 16 and start the virtual test bench 10 directly with their own configurations, applications, and environment.

Testing an application in multiple versions of the head unit software 18, 30 is cumbersome. It may take days until developers find a place where they may go for testing their applications in the specific versions. The virtual test bench 10 may all be put together in virtual groups where the user 24 may simultaneously test their applications in many different versions.

The virtual test bench 10 may have the virtual display 36 deployed and updated in the cloud by specialized teams that are not always available to go on-site and the help local teams. The virtual display 36 is forwarded over the network to the decentral electronic computing device 22, and all controls, which are available in the real vehicle, allow the user 24 to control its function, interact with the virtual touch screen, and see the exact reactions and visual appearance and tactile appeal of the real screen. This is a very valuable feature for developers, product owners, or anybody who wants to share design/functionality in a realistic setting to other stakeholders or during the development phase. The mentioned screens may be for example a screen of a mobile phone, a touchscreen display, an instrument cluster or other types of screens.

According to the embodiment, early feedback and testing may be provided by simply sharing the information of the virtual test bench 10. A team in a first region 32 may simply start the decentral electronic computing device 22 and instantly gain access to a running virtual test bench 10 in any other region 32.

Third party teams that are invested in building head unit applications may own private virtual test benches 10 with exclusive access and may manipulate their own configuration and control access. Furthermore, it is possible to hook virtual test benches 10 to their Cl/CD-pipelines to have end-to-end tests hooked up for increased scrutiny of every new application deployment, evaluating their application behavior in multiple variances of the head unit software 18, 30 and multiple regions 32, for example, China, Europe or America.

1-10. (canceled)

11. A method for virtual testing of at least one head unit of at least one motor vehicle by a virtual test bench, the method comprising:
providing a central electronic computing device of the virtual test bench and providing at least two different versions of characterizing software of the at least one head unit on the central electronic computing device;
enabling a data communication between a decentral electronic computing device and the central electronic computing device;
transmitting an input of a user of the decentral electronic computing device to the central electronic computing device via the data communication;
virtually testing, by the central electronic computing device, the input of the user depending on the provided at least two different versions of the characterizing software, wherein the at least two different versions of the characterizing software are virtually tested simultaneously;
transmitting, by the central electronic computing device, a result of the virtual testing to the decentral electronic computing device via the data communication; and
displaying the result on a display device of the decentral electronic computing device for the user.

12. The method of claim 11, wherein the at least two different versions are provided for at least two different geographic regions.

13. The method of claim 11, wherein the central electronic computing device is a cloud server.

14. The method of claim 11, wherein the at least two different versions of the characterizing software comprises a plurality of different versions of the characterizing software, and the input is virtually tested by the plurality of different versions characterizing software.

15. The method of claim 11, wherein the at least two different versions of the characterizing software is editable by an operator of the central electronic computing device.

16. The method of claim 11, wherein a plurality of different head units of a plurality of different motor vehicles is virtually tested by the virtual test bench.

17. The method of claim 11, wherein the central electronic computing device comprises a display emulator for virtual testing of a virtual display of the at least one head unit and the virtual display is transmitted to the decentral electronic computing device via the data communication and displayed on the display device.

18. A computer program product comprising non-transitory computer instructions for virtual testing of at least one head unit of at least one motor vehicle by a virtual test bench using a central electronic computing device of the virtual test bench and at least two different versions of characterizing software of the at least one head unit on the central electronic computing device, the non-transitory computer instructions, when executed the central electronic computing device, cause the central electronic computing device to:
enable a data communication with a decentral electronic computing device;
receive an input of a user of the decentral electronic computing device via the data communication;
virtually test the input of the user depending on the provided at least two different versions of the characterizing software, wherein the at least two different versions of the characterizing software are virtually tested simultaneously; and
transmit a result of the virtual testing to the decentral electronic computing device via the data communication, wherein the result is displayed on a display device of the decentral electronic computing device for the user.

19. A virtual test bench for virtual testing of at least two different versions of characterizing software of at least one head unit of at least one motor vehicle, the virtual test bench comprising:
at least one central electronic computing device, which is configured to enable a data communication with a decentral electronic computing device;
receive an input of a user of the decentral electronic computing device via the data communication;
virtually test the input of the user depending on the provided at least two different versions of the characterizing software, wherein the at least two different versions of the characterizing software are virtually tested simultaneously; and
transmit a result of the virtual testing to the decentral electronic computing device via the data communication, wherein the result is displayed on a display device of the decentral electronic computing device for the user.
